(19) United States
(12) Patent Application Publication
(10) Pub. No.: US 2004/0096997 A1
(43) Pub. Date: May 20, 2004

(54) Method for manufacturing GaN compound semiconductor light emitting device

(75) Inventor: Joon-Seop Kwak, Kyungki-do (KR)

Correspondence Address: BURNS DOANE SWECKER & MATHIS L L P, POST OFFICE BOX 1404, ALEXANDRIA, VA, 22313-1404, US

(73) Assignee: Samsung Electronics Co., Ltd., Suwon-city (KR)

(21) Appl. No.: 10/694,814

(22) Filed: Oct. 29, 2003

(30) Foreign Application Priority Data
Nov. 15, 2002 (KR) 2002-71045

(51) Int. Cl. H01L 21/00

(52) U.S. Cl. 438/22

(57) ABSTRACT

A method for manufacturing a GaN compound semiconductor light emitting device is provided. In the method for manufacturing a light emitting device including at least one layer of a p-type compound semiconductor layer on an active layer where light is generated and a p-type electrode on the p-type compound semiconductor layer, after forming the p-type compound semiconductor layer on the active layer, the resultant structure is annealed twice, and the p-type electrode is formed on the annealed p-type compound semiconductor layer. As a result of the annealing performed twice, the resistance of the p-GaN layer is lowered, contact resistance between the p-GaN layer and the p-type electrode is lowered even when the p-type electrode is formed as a single metal layer, and thus, the driving voltage of the light emitting device is lowered. When using the method, a p-type electrode of a light emitting device can be manufactured from various kinds of materials by applying various techniques.

### BACKGROUND OF THE INVENTION

This application claims priority from Korean Patent Application No. 2002-71045, filed on Nov. 15, 2002, in the Korean Intellectual Property Office, the disclosure of which is incorporated herein in its entirety by reference.

1. Field of the Invention

The present invention relates to a method for manufacturing a semiconductor light emitting device, and more particularly, to a method for manufacturing a light emitting diode using a GaN compound semiconductor.

2. Description of the Related Art

Representative examples of semiconductor light emitting devices are laser diodes (LDs) and light emitting diodes (LEDs). With the development of high-density data rewritable optical recording media, such as CD-Rs, CD-RWs, and DVDs, LDs have been widely used as efficient optical recording means therefor. Especially, GaN compound semiconductor LDs which emit a blue or green short laser beam have wide applications, for example, as a light source for DVD systems and for full color displays (FCD).

LEDs are widely used as a light source in the optical communications field or to display the state of operation of electronic devices.

FIGS. 1 and 2 are sectional views of a conventional GaN compound semiconductor LED and LD, respectively.

Referring to FIG. 1, a conventional LED includes an n-GaN layer 12 on a substrate 10. The n-GaN layer 12 includes a first region R1 and a second region R2 with a step therebetween. The second region R2 is thinner than the first region R1. An active layer 14, a p-GaN layer 16, and a p-type electrode 18 are sequentially formed on the first region R1 of the n-GaN layer 12. An n-type electrode 22 is formed on the second region R2 of the n-GaN layer 12.

Referring to FIG. 2, a conventional LD includes an n-GaN layer 12 on a substrate 10. Similar to the LED of FIG. 1, the n-GaN layer 12 includes a first region R1 and a second region R2. An n-type electrode 40 is formed on the second region R2. A resonator layer is formed on the first region R1 of the n-GaN layer 12. The resonator layer includes an n-cladding layer 24, an n-waveguide layer 26 having a larger refractive index than the n-cladding layer 24, an active layer 28 having a larger refractive index than the n-waveguide layer 26, and a p-waveguide layer 30 having a smaller refractive index than the active layer 28. A p-cladding layer 32 having a smaller refractive index than the p-waveguide layer 30 is formed on the p-waveguide layer 30. The p-cladding layer 32 has a ridge at the center region on the top surface thereof. A p-GaN layer 34 is formed on the ridge of the p-cladding layer 32 as a contact layer. A protective layer 36 is formed to cover the entire surface of the p-cladding layer 32 and an edge region of the p-GaN layer 34. A p-type electrode 38 is formed on the protective layer 36 to contact the p-GaN layer 34.

The p-type electrode 18 of the conventional LED of FIG. 1 and the p-type electrode 38 of the LD of FIG. 2 are manufactured as illustrated in FIGS. 3 and 4. In FIGS. 3 and 4, both p-type electrodes for an LED and an LD are denoted by reference numeral 38 for convenience of illustration.

Referring to FIG. 3, a first metal layer 38a having lower oxidation potential and a second metal layer 38b having greater oxidation potential are sequentially formed on the p-GaN layer 16(34) acting as a contact layer to form the p-type electrode 38. The first and second metal layers 38a and 38b are formed of a nickel layer and gold layer, respectively. After the formation of the p-type electrode 38, constituent atoms of the second metal layer 38b are diffused through the first metal layer 38a into the p-type GaN layer 16(34) by annealing. As a result, the second metal layer 38b is located between the p-GaN layer 16(34) and the first metal layer 38a, so that contact resistance between the p-GaN layer 16(34) and the p-type electrode 38 is lowered.

In conventional methods for manufacturing GaN compound semiconductor LEDs, the p-type electrode 18 is formed based on the thermodynamics of the first and second metal layers on the p-GaN layer. Therefore, limited kinds of materials are available for the p-type electrode.

### SUMMARY OF THE INVENTION

The present invention provides a method for manufacturing a GaN compound semiconductor light emitting device that is compatible with various kinds of metallic materials for a p-type electrode and which can lower contact resistance between the p-type electrode and a p-GaN layer and driving voltage of the light emitting device.

In accordance with one aspect of the present invention, there is provided a method for manufacturing a light emitting device comprising at least one layer of a p-type compound semiconductor layer on an active layer where light is generated and a p-type electrode on the p-type compound semiconductor layer, the method comprising: forming the p-type compound semiconductor layer on the active layer and annealing twice the resultant structure; and forming the p-type electrode on the annealed p-type compound semiconductor layer.

In the above method, annealing twice the resultant structure may comprise: performing first annealing on the resultant structure in a nitrogen atmosphere after the p-type compound semiconductor layer is formed; and performing second annealing on the first annealed resultant structure in an oxygen atmosphere. In this case, the first annealing may be performed at an atmospheric pressure at a temperature of 300-1000° C. for a duration from 30 seconds to 3 hours. The second annealing may be performed at an atmospheric pressure at a temperature of 300-1000° C. for a duration from 30 seconds to 3 hours.

For a light emitting diode (LED), the p-type compound semiconductor layer may be formed of a p-GaN layer. For a laser diode (LD), the p-type compound semiconductor layer may be formed as a multi-layer, and the uppermost layer of the p-type compound semiconductor layer that contacts the p-type electrode may be formed of a p-GaN layer.

Another method for manufacturing a light emitting device according to the present invention comprises: forming at least one layer of n-type compound semiconductor layer on a substrate; forming an active layer on the n-type compound semiconductor layer, the active layer where light is generated; forming at least one layer of p-type compound semiconductor layer on the active layer; annealing twice the resultant structure including the p-type compound semiconductor layer; forming a p-type electrode on the p-type compound semiconductor layer; and forming an n-type electrode to contact the n-type compound semiconductor layer.

According to the present invention, due to the annealing performed twice, the resistance of the p-GaN layer is lowered, and the contact resistance between the p-GaN layer and the p-type electrode is lowered even when the p-type electrode is formed as a single metal layer. Accordingly, the driving voltage of the light emitting device is lowered. In addition, any metal layer can be used for the p-type electrode in the present invention. In other words, more various kinds of materials are available for the p-type electrode, as opposed to using conventional methods, and thus, various techniques can be applied to manufacture the p-type electrode.

### BRIEF DESCRIPTION OF THE DRAWINGS

The above and other features and advantages of the present invention will become more apparent by describing in detail exemplary embodiments thereof with reference to the attached drawings in which:

FIGS. 1 and 2 are sectional views of a conventional GaN compound semiconductor light emitting diode (LED) and laser diode (LD), respectively;

FIGS. 3 and 4 are sectional views illustrating each step of a method for manufacturing a p-type electrode for the LED of FIG. 1 and the LD of FIG. 2;

FIGS. 5 through 12 are sectional views illustrating a method for manufacturing a GaN compound semiconductor LD according to an embodiment of the present invention;

FIGS. 13 through 15 are sectional views illustrating LDs having various structures that can be manufactured using the method for manufacturing a GaN compound semiconductor light emitting device according to the present invention;

FIGS. 16 and 17 are sectional views illustrating LEDs having various structures that can be manufactured using the method for manufacturing a GAN compound semiconductor light emitting device according to the present invention;

FIG. 18 is a flowchart illustrating each step of a method for manufacturing a GaN compound semiconductor light emitting device according to the present invention;

FIG. 19 is a graph of current versus voltage illustrating the ohmic contact characteristics between a p-GaN layer and a p-type electrode in a GaN compound semiconductor light emitting device manufactured using the method according to the present invention and GaN compound semiconductor light emitting devices manufactured using conventional methods; and

FIGS. 20 and 21 are graphs illustrating contact resistance and sheet resistance characteristics between the p-GaN layer and the p-type electrode, respectively, for GaN compound semiconductor light emitting devices manufacturing using the method according to the present invention and GaN compound semiconductor light emitting devices manufactured using conventional methods.

### DETAILED DESCRIPTION OF THE INVENTION

The present invention now will be described in detail with reference to the accompanying drawings, in which exemplary embodiments of the invention are shown. In the drawings, the thickness of layers and regions are exaggerated for clarity.

A feature of a method for manufacturing a light emitting device, such as a laser diode (LD) or a light emitting diode (LED), according to the present invention lies in the thermal process of a p-GaN layer, which is performed before a p-type electrode is formed on the p-GaN layer. This thermal process of the p-GaN layer will be described below with reference to the formation of a GaN compound semiconductor LD.

FIGS. 5 through 12 are sectional views illustrating each step of a method for manufacturing a GaN compound semiconductor LD according to an embodiment of the present invention.

Referring to FIG. 5, a buffer layer 202 for improved contact with the overlying layer, an n-type compound semiconductor layer 203, a n-type cladding layer 204, an active layer 205 from which a laser beam is emitted, a p-type cladding layer 206 are sequentially stacked on a substrate 201. The buffer layer 202 is formed of a GaN layer, the n-type compound semiconductor layer 203 is formed of an n-GaN layer, the n-type cladding layer 204 is formed of an n-AIGaN layer, the active layer 205 is formed of an InGaN layer, and the p-type cladding layer 206 are formed of a p-AIGaN layer.

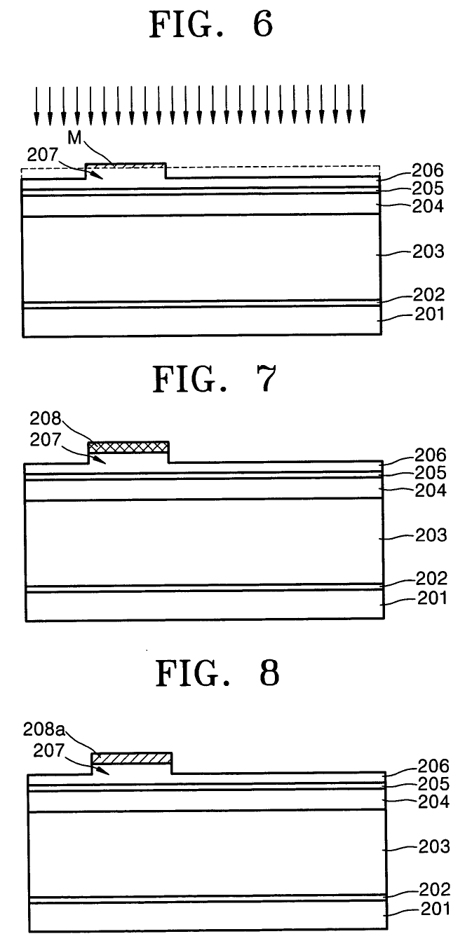

Referring to FIG. 6, a mask M is formed on the p-type cladding layer 206 to define a region of the p-type cladding layer 106. A region of the p-type cladding layer 206 which is not covered with the mask M is dry etched to a depth using photolithography, and the mask M used is removed. As a result, a ridge stripe 207 is formed on the region of the p-type cladding layer 106 from which the mask M is removed. As damage from the dry etching, an N-depletion region (not shown) results in the p-type cladding layer 106 at both sides of the ridge stripe 207. Because the N-depletion region has a donor energy level, the p-type cladding layer 104 at both sides of the ridge stripe 27 acts as a semi-insulator. An electrical current flows through only the ridge stripe 207, thereby allowing the LD to operate in a single traverse mode with more ease.

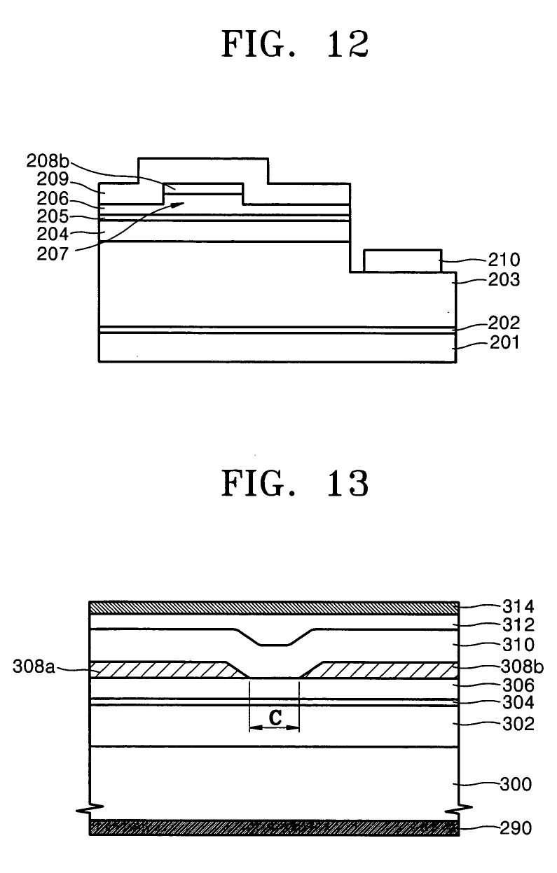

Referring to FIG. 7, a p-GaN layer 208 acting as a contact layer is formed on the ridge stripe 207 and subjected to annealing twice. Annealing is performed to lower contact resistance between the p-GaN layer 208 and a p-type electrode 209 (refer to FIG. 11), which is formed on the p-GaN layer 208 in a subsequent process.

First annealing is performed on the resulting structure in which the p-GaN layer 208 has been formed. As a result of the first annealing, the p-GaN layer 208 is activated, and impurities therein, such as hydrogen, are diffused out of the p-GaN layer 208.

The first annealing may be performed in any kind of annealing apparatus, and preferably, in a furnace. The first annealing is performed, preferably at an atmospheric pressure and in a nitrogen atmosphere, for example, at a temperature of 300-1000° C., preferably, 500° C., for a duration from 30 seconds to 3 hours, preferably, 1 minute. In FIG. 8, reference numeral 208a denotes a first annealed GaN layer formed as a result of the first annealing on the p-GaN layer 208.

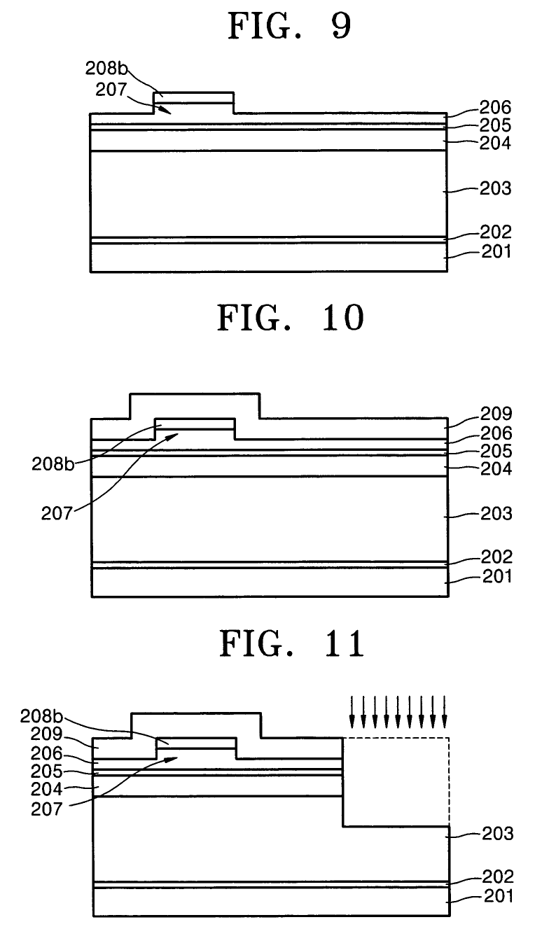

Next, the first annealed GaN layer 208 is subjected to a second annealing. The second annealing is performed at an atmospheric pressure, and preferably, in an O₂ atmosphere, unlike the first annealing, at 0-1000° C., preferably, 500° C., for a duration from 30 seconds to 10 hours, preferably, 30 minutes. Similar to the first annealing, the second annealing may be performed in any kind of annealing apparatus, and preferably, in a furnace. In FIG. 9, reference numeral 208b denotes a second annealed GaN layer 208b formed as a result of the second annealing on the first annealed GaN layer 208a.

Due to the formation of the second annealed GaN layer 208b from the p-GaN layer 108 through the first and second annealing processes, contact resistance between the second annealed GaN layer 208b and the p-type electrode (FIG. 11) formed in a subsequent process is lowered. A probable reason for this is the elimination of hydrogen that remained in the first annealed GaN layer 208a after the first annealing, which would combine with p-type dopants, for example, Mg, and increase the resistance of the first annealed GaN layer 208a, through a direct or indirect reaction with oxygen during the second annealing process. Another probable reason for the reduction of the contact resistance is that oxygen-induced defects occur in the first annealed GaN layer 208a during the second annealing, which increase current conduction, so the contact resistance of the second annealed GaN layer 208b can be lowered.

Referring to FIG. 10, a metal layer 209, hereinafter, referred to as a p-type electrode, is formed on the resulting structure from the second annealing to cover the second annealed GaN layer 208b. The p-type electrode 209 is formed of a metal layer having a large work function, and preferably, as a single layer. Alternatively, the p-type electrode 209 may be formed as a multi-layer. Examples of a metal layer having a large work function for the p-type electrode 209 include a palladium (Pd) layer, a nickel (Ni) layer, a platinum (Pt) layer, a gold (Au) layer, etc. Alternatively, the p-type electrode 209 may be formed as a multi-layer, for example, a Ni/Au layer, using at least two layers selected from the forgoing metal layers.

After the formation of the p-type electrode 209, a region of the p-type electrode 209 below which the second annealed GaN layer 208b is not located is etched, as shown in FIG. 11, to provide an n-type electrode region. The second annealed GaN layer 208b is protected by a mask (not shown) during the etching process. The etching is performed until at least a portion of the n-type compound semiconductor layer 203 is removed. Next, the mask used is removed.

Referring to FIG. 12, an n-type electrode 210 is formed on an exposed etched region of the n-type compound semiconductor layer 203 to provide a complete GaN compound semiconductor LD.

In forming the p-type electrode 209, alternatively, the p-type electrode 209 may be formed on only the second annealed GaN layer 208b. Next, a protective layer may be formed around the p-type electrode 209.

The method for manufacturing a light emitting device according to the present invention, which is characterized by involving annealing performed twice on the p-GaN layer prior to formation of a p-type electrode thereon, can be applied for various structures of LDs, including a structure illustrated in FIGS. 13 through 15 described later, different from the structure of the LD of FIG. 12.

A GaN compound semiconductor LD having n-type and p-type electrodes 290 and 314 on its opposing surfaces, respectively, with multiple layers for laser emission between the n-type and p-type electrodes 290 and 314, is shown in FIG. 13. In particular, referring to FIG. 13, a substrate 300 is formed on the n-type electrode 290. The substrate 300 is an n-type compound semiconductor substrate, i.e., n-GaN substrate. An n-type cladding layer 302, an active layer 304 having a multi-quantum well (MQW) structure, where laser emission occurs by combination of holes and electrons, and a p-type first cladding layer 306 are sequentially formed on the substrate 300. The n-type cladding layer 302 is an n-type compound semiconductor layer having a lower refractive index than the active layer 304, for example, n-AIGaN layer. The p-type first cladding layer 306 is a p-type compound semiconductor layer having a lower refractive index than the active layer 304, for example, p-InAIGaN layer. The active layer 304, the n-type cladding layer 302, and the p-type first cladding layer 306 forms a resonator layer for laser emission. First and second current barrier layers 308a and 308b are formed on the p-type first cladding layer 306 separated apart by a gap. A current for laser emission is applied through only the gap between the first and second current barrier layers 308a and 308b. In other words, the first and second current barrier layers 308a and 308b together defines a channel region C having a predetermined width. The channel region C has a stripe shape. A p-type second cladding layer 310 is formed on the first and second current barrier layers 308a and 308b to contact a region of the p-type cladding layer 306 that is exposed through the channel region C. The p-type first and second cladding layers 306 and 310 are formed of the same kind of p-type compound semiconductor, thereby forming a p-n-p junction together with the first and second current barrier layers 306a and 306b, which are n-type compound semiconductor layers. As a result, a depletion layer is at an interface between the p-type first and second cladding layers 306 and 310 and the first and second current barrier layers 308a and 308b. In other words, the first and second current barrier layers 308a and 308b block a current from entering the active layer 304 through a region other than the channel region C.

Referring to FIG. 13, a region of the p-type second cladding layer 310 aligned with the channel region C is recessed over the other region due to a step between the channel region C and the first and second current barrier layers 308a and 308b underlying the p-type second cladding layer 310. A flat p-type contact layer 312 is formed on the surface of the p-type second cladding layer 310. The p-type contact layer 312 is a p-GaN layer. The p-type electrode 314 is formed on the p-contact layer 312 as an ohmic contact layer.

In the above method for manufacturing the LD of FIG. 13, prior to the formation of the p-type electrode 314 on the p-type contact layer 312, annealing may be performed on the p-type contact layer 312 twice under the above-described conditions.

Another structure of a GaN compound semiconductor LD is shown in FIG. 14. Referring to FIG. 14, an n-type compound semiconductor layer 402 is formed on a durable substrate 400, such as a sapphire substrate. The n-type compound semiconductor layer 402 is a GaN Group III-V nitride compound semiconductor layer, preferably, a direct transition type, more preferably, an n-GaN layer. A via hole 404 whose opening faces downward is formed in the substrate 400. A region of the bottom of the n-type compound semiconductor layer 402 is exposed through the via hole 402. A conductive layer 406 is formed on the bottom of the substrate 400 to contact the region of the n-type compound semiconductor layer 402 exposed through the via hole 404. The conductive layer 403 serves as a lower electrode.

An n-type cladding layer 408 is formed on the n-type compound semiconductor layer 402. A first waveguide layer 500, an active layer 503, and a second waveguide layer 504, which form a resonator layer, are sequentially formed on the n-type cladding layer 408. The first and second waveguide layers 500 and 504 are GaN Group III-V nitride compound semiconductor layers, preferably, an n-GaN layer and a p-GaN layer, respectively. The refractive indices of the first and second waveguide layers 500 and 504 are larger than the n-type cladding layer 408. The active layer 502 is a GaN Group III-V nitride compound semiconductor layer, for example, InGaN layer containing a predetermined amount of indium. The refractive index of the active layer 502 is larger than that of the first and second waveguide layers 500 and 504. The refractive index of the resonator layer becomes smaller outward from its core region. Therefore, optical loss becomes smaller, and laser emission efficiency in the active layer 502 becomes greater.

A p-type cladding layer 506 with a ridge region at its center is formed on the second waveguide layer 504. A p-type compound semiconductor layer 508 is formed on the ridge region of the p-type cladding layer 506. The p-type compound semiconductor layer 508 may be a p-GaN layer. A protective layer 510 is formed to cover the entire p-type compound cladding layer 506 and an edge of the p-type compound semiconductor layer 508. A conductive layer 512 acting as an upper electrode is formed on the protective layer 510 to contact the p-type compound semiconductor layer 508.

In manufacturing a GaN compound semiconductor LD having the structure of FIG. 14, prior to formation of the conductive layer 512, the p-type compound semiconductor layer 508 is subjected to annealing twice under the same conditions as described above. Annealing may be performed twice after or prior to the formation of the protective layer 510.

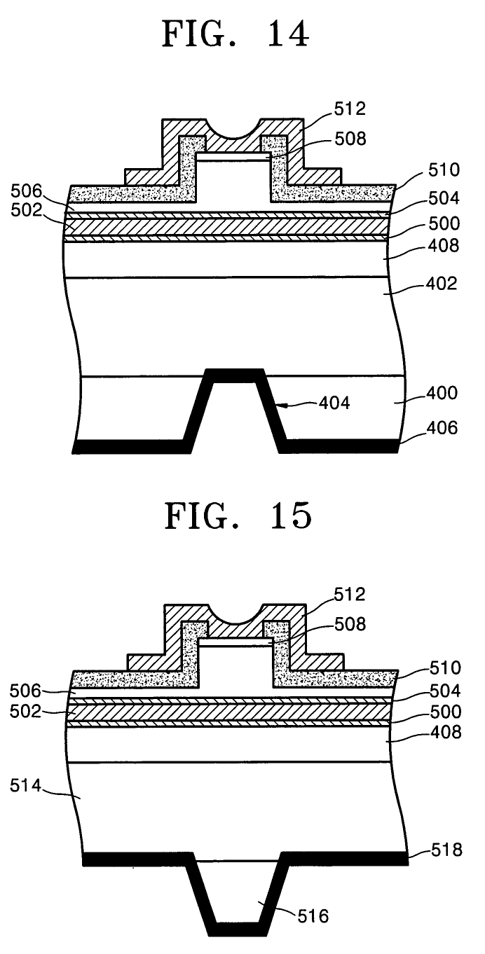

FIG. 15 shows another structure of a GaN compound semiconductor LD, which is the same as that of FIG. 14 except of the shapes of the durable substrate and the lower electrode. In FIG. 15, the same reference numerals as those of FIG. 14 denote the same elements as those in FIG. 14.

Referring to FIG. 15, a durable substrate pattern 516 remains at the center of the bottom of the n-type compound semiconductor layer 514, and a conductive layer 518 acting as a lower electrode is formed to cover the bottom of the n-type compound semiconductor layer 154 and the durable substrate pattern 516. The structure of the stack of layers sequentially formed on the n-type compound semiconductor layer 514 is the same as in FIG. 14, and thus, a description thereon will be omitted here.

In manufacturing a GaN compound semiconductor LD having the structure of FIG. 15, annealing is performed twice on the p-type compound semiconductor layer 508 contacting a p-type electrode, after or prior to the formation of the protective layer 510, as described above.

A method for manufacturing a light emitting device according to the present invention can be applied to various LEDs, in addition to LDs having the structures of FIGS. 12 through 15.

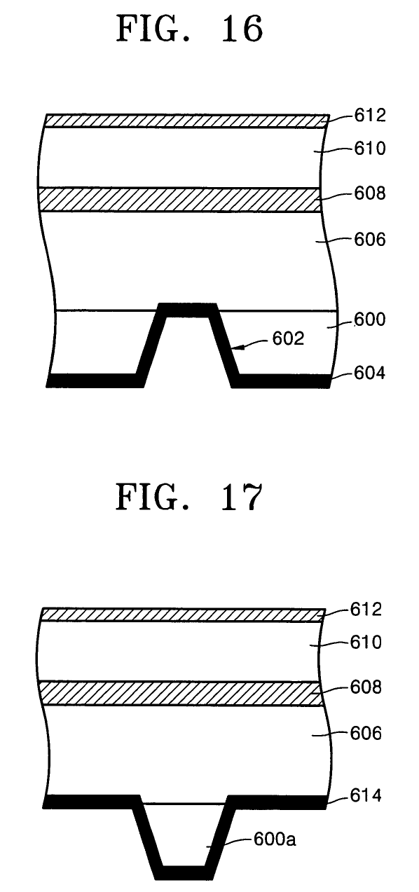

An example of a LED, which can be manufactured using the method according to the present invention, is shown in FIG. 16. Referring to FIG. 10, a LED include a sapphire substrate 600 and an n-type compound semiconductor layer 606, an active layer 608, and a p-type compound semiconductor layer 610, which are sequentially deposited on the sapphire substrate 600 to form a stack, with upper and lower electrodes 612 and 604 formed on opposing surfaces of the stack to face each other. A via hole 600 whose opening faces downward is formed in the sapphire substrate 600 to expose a region of the bottom of the n-type compound semiconductor layer 606. The lower electrode 604 is formed to cover the entire sapphire substrate 600 and contact the exposed region of the n-type compound semiconductor layer 606.

In manufacturing an LED having the structure of FIG. 16, the n-type compound semiconductor layer 610 is annealed twice prior to the formation of the p-type upper electrode 612 thereon under the same conditions as described above.

Another example of a LED, which can be manufactured using the method according to the present invention, is shown in FIG. 17. The structure of the LED of FIG. 17 is the same as that of FIG. 16, except that a sapphire substrate pattern 600a remains only in a region of the bottom of the n-type compound semiconductor layer 606, and a lower electrode 614 is formed to cover the entire sapphire substrate pattern 600a and an exposed region of the bottom of the n-type compound semiconductor layer 606. In other words, the stack of layers formed on the n-type compound semiconductor layer 606 is the same as that of FIG. 16 and is manufactured by the same method as described above.

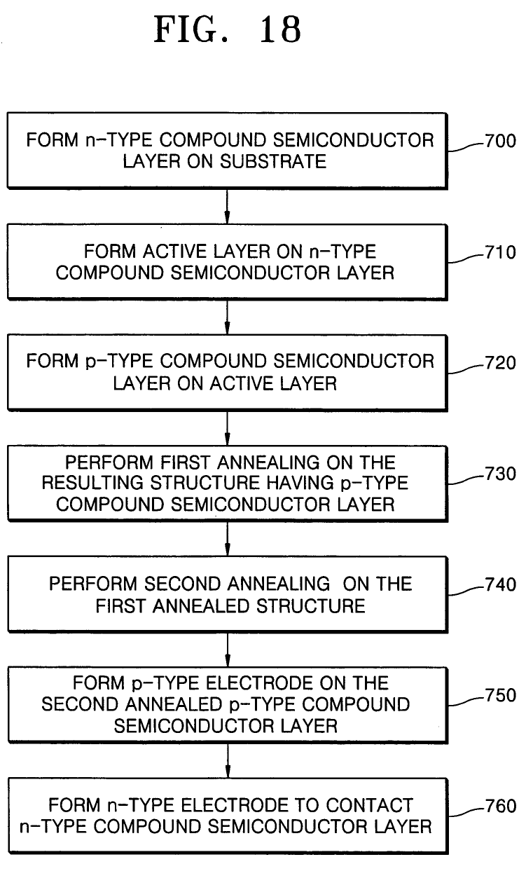

FIG. 18 is a flowchart illustrating a method for manufacturing the above-described light emitting devices according to the present invention. Referring to FIG. 18, an n-type compound semiconductor layer is formed on a substrate (step 700). The substrate may be a compound semiconductor substrate, such as a GaN substrate, preferably, a durable substrate, such as a sapphire substrate. In either case, it is preferable that the n-type compound semiconductor layer is formed of an n-type GaN layer.

The method applied to form the n-type compound semiconductor layer varies for LDs or LEDs. For LDs, it is preferable that the n-type compound semiconductor layer is formed as a multi-layer, for example, including an n-type cladding layer and/or an n-type waveguide layer, as illustrated in FIGS. 12 through 15. For an LED not requiring a cladding layer or a waveguide layer, it is preferable that the n-type compound semiconductor layer is formed as a single layer, as illustrated in FIGS. 16 and 17.

Next, an active layer is formed on the n-type compound semiconductor layer (step 710). It is preferable that the active layer is formed of a compound semiconductor layer having a MQW structure.

Next, a p-type compound semiconductor layer is formed on the active layer (step 720). Similar to the n-type compound semiconductor layer, the p-type compound semiconductor layer is formed as a multi-layer or a single layer depending on the kind of the light emitting device manufactured. In an LD, the p-type compound semiconductor layer may include all of the layers stacked between the active layer and the p-type electrode. Accordingly, the contact layer (p-GaN layer) underlying the p-type electrode and the protective layer 510 may be included in the p-type compound semiconductor layer when an LD has the structure of FIG. 14.

Next, the resulting structure with the p-type compound semiconductor layer is annealed (first annealing) under the same conditions as described above (step 730).

Second annealing is performed on the first annealed structure under the same conditions as described above (step 740).

Next, a p-type electrode is formed on the second annealed p-type compound semiconductor layer. In an LD, a p-type electrode is formed on a contact layer of the p-type compound semiconductor layer, as shown in FIGS. 14 and 15. In a LED, a p-type electrode is formed on the entire p-type compound semiconductor layer 610 formed on the active layer 608, as shown in FIGS. 16 and 17.

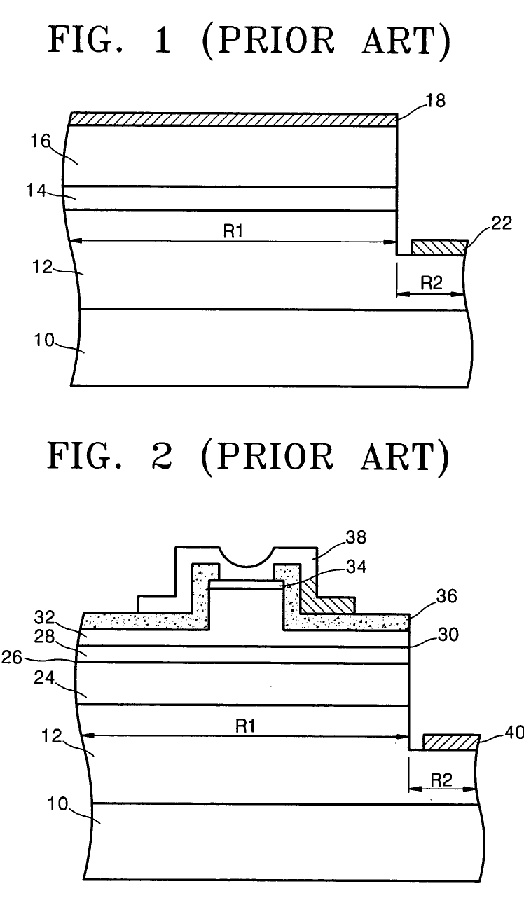

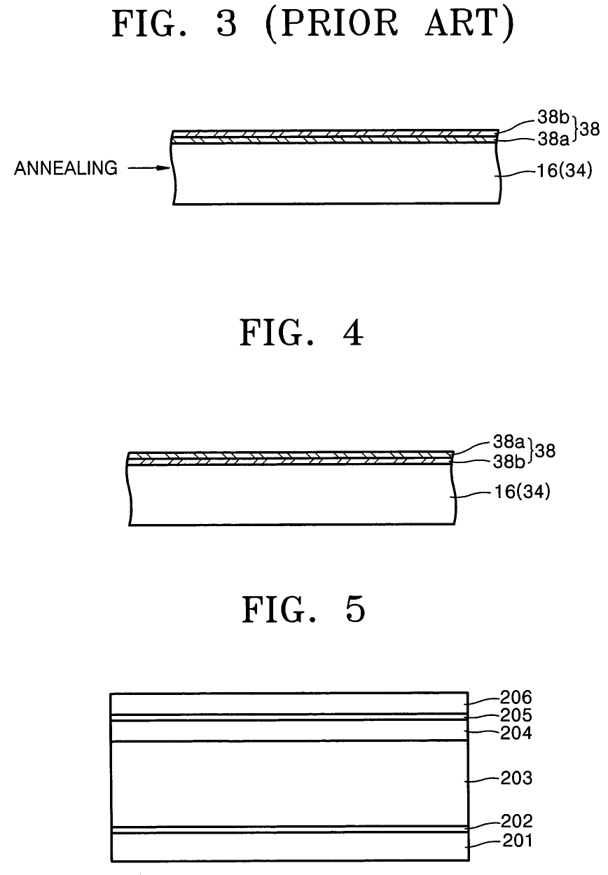

Finally, an n-type electrode is formed to contact the n-type compound semiconductor layer (step 760). In step 760, the n-type electrode may be formed facing the same or the opposite direction as the p-type electrode. In the former, like the LDs of FIGS. 1 and 12, the p-type semiconductor layer and the active layer 14(205) are sequentially removed to expose a region of the n-type compound semiconductor layer 12(203), wherein the thickness of the exposed region of the n-type compound semiconductor layer 12(203) becomes smaller. Next, the n-type electrode 22(210) is formed on the exposed region of the n-type compound semiconductor layer 12(203).

In the latter, like the LDs of FIGS. 13 through 15 and LEDs of FIGS. 16 and 17, after the p-type electrode 314 (512, 612) is formed, the n-type electrode 190 (406, 518, 604, and 614) is formed in a position facing the p-type electrode 314 (512, 612). In FIG. 14, the n-type electrode 406 is connected to a region of the n-type compound semiconductor layer 402 that is exposed through a via hole 404 formed in the substrate 400.

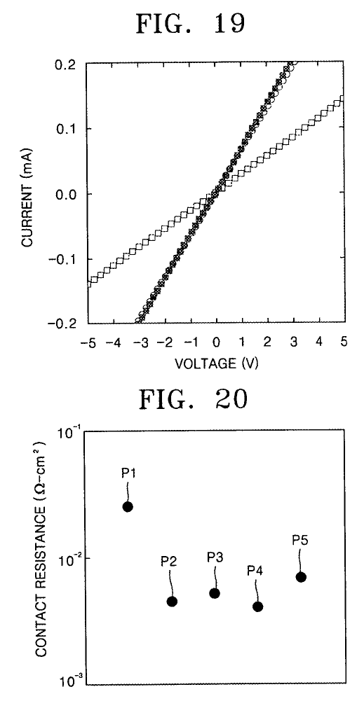

Current-voltage characteristics, contact resistance between the p-type electrode and the p-GaN layer, and sheet resistance of the p-GaN layer were measured using light emitting devices manufactured according to the present invention and conventional light emitting devices. The results are shown in FIGS. 19 through 21.

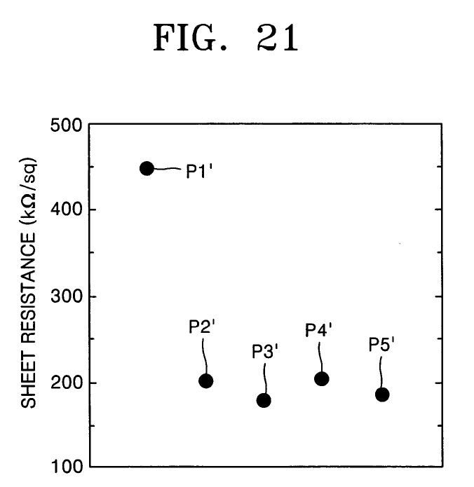

FIG. 19 is a graph showing current versus voltage characteristics, FIG. 20 is a graph showing change in contact resistance, and FIG. 21 is a graph showing change in sheet resistance. In FIG. 19, “▪” is for a light emitting device manufactured according to an embodiment of the present invention having a p-GaN layer that has undergone annealing twice and a p-type electrode formed as a single metal layer (hereinafter, “case 1”), and “□L” and “◯” are for light emitting devices manufactured and activated using a conventional method and having a p-type electrode formed as a single metal layer (case 2) and as a double metal layer (case 3), respectively.

Comparing case 1 and case 2, when the p-type electrode is formed as a single metal layer, for example, a nickel (Ni) layer, the method according to the present invention provides better current-voltage characteristics than the conventional method.

Comparing case 1, where the p-type electrode was formed as a single Ni layer using the method according to the present invention, and case 3, where the p-type electrode was formed as a Ni/Au layer using the conventional method, current-voltage characteristics are similar between the two cases.

In FIG. 20, P1 and P2 denote contact resistance between the p-type electrode and the p-GaN layer for case 2 and case 3, respectively. P3, P4, and P5 denote contact resistance for case 1 when the p-type electrode is formed of a Pt layer, an Au layer, and a Ni layer, respectively.

Comparing contact resistance between case 1 and case 2, contact resistance between the p-type electrode formed as a single metal layer and the p-GaN layer is far lower when the method according to the present invention (P3, P4, and P5) is applied than when the conventional method (P1) is applied.

For case 3 (P2), where the p-type electrode is formed as a multi-layer using the conventional method, there is no great difference in contact resistance from case 1, where the p-type electrode is formed as a single metal layer using different materials (P3, P4, and P5) according to the method of the present invention.

In FIG. 21, P1′ and P2′ denote sheet resistance of the p-GaN layer ohmic contacting the p-type electrode for case 2 and case 3, respectively. P3′, P4′, and P5′ denote sheet resistance of the p-GaN layer for case 1 when the p-type electrode is formed of a Pt layer, an Au layer, and a Ni layer, respectively. As is apparent from FIG. 21, changes in sheet resistance between the present invention and the prior art are similar to those in contact resistance described with reference to FIG. 20.

As is apparent from the results of FIGS. 19 through 21, when the p-type electrode is formed as a single metal layer using the method according to the present invention, current-voltage, contact resistance, and sheet resistance characteristics are improved to be comparable with the p-type electrode formed as a multi-layer using the conventional method, regardless of the material used to form the single-layered p-type electrode.

As described above, in a method for manufacturing a GaN compound semiconductor light emitting device according to the present invention, a p-GaN layer is annealed twice prior to formation of a p-type electrode on the p-GaN layer, wherein second annealing is performed in an oxygen atmosphere. In a light emitting device manufactured using this method, the resistance of the p-GaN layer is lowered as a result of the annealing, the contact resistance between the p-GaN layer and the p-type electrode is lowered even when the p-type electrode is formed as a single layer, and thus, the driving voltage of the light emitting device is lowered. In addition, any metal layer can be used for the p-type electrode in the present invention. In other words, more various kinds of materials are available for the p-type electrode, as opposed to using conventional methods, and thus, various techniques can be applied to manufacture the p-type electrode.

While the present invention has been particularly described in the above with reference to embodiments thereof, the above embodiments of the present invention are for illustrative purposes and are not intended to limit the scope of the invention. For example, it will be obvious to those of ordinary skill in the art that annealing twice the p-GaN layer prior to formation of the p-type electrode on the p-GaN layer can be applied to any LD and LED having a structure different from the above-described embodiments, without departing from the spirit and scope of the present invention as defined by the following claims.

What is claimed is:

1. A method for manufacturing a light emitting device comprising at least one layer of a p-type compound semiconductor layer on an active layer where light is generated and a p-type electrode on the p-type compound semiconductor layer, the method comprising:
forming the p-type compound semiconductor layer on the active layer and annealing twice the resultant structure; and
forming the p-type electrode on the annealed p-type compound semiconductor layer.

2. The method of claim 1, wherein annealing twice the resultant structure comprises:
performing first annealing on the resultant structure in a nitrogen atmosphere after the p-type compound semiconductor layer is formed; and
performing second annealing on the first annealed resultant structure in an oxygen atmosphere.

3. The method of claim 2, wherein the first annealing is performed at an atmospheric pressure at a temperature of 300-1000° C. for a duration from 30 seconds to 3 hours.

4. The method of claim 2, wherein the second annealing is performed at an atmospheric pressure at a temperature of 300-1000° C. for a duration from 30 seconds to 3 hours.

5. The method of claim 1, wherein the p-type electrode is formed as a single layer or a multi-layer.

6. The method of claim 5, wherein the single layer is formed of a Pd layer, a Ni layer, a Pt layer, or an Au layer.

7. The method of claim 5, wherein the multi-layer is formed of at least two layers selected from the group consisting of a Pd layer, a Ni layer, a Pt layer, and an Au layer.

8. The method of claim 1, wherein the p-type compound semiconductor layer is formed of a p-GaN layer.

9. The method of claim 1, wherein the p-type compound semiconductor layer is formed as a multi-layer, and the uppermost layer of the p-type compound semiconductor layer that contacts the p-type electrode is formed of a p-GaN layer.

10. The method of claim 2, wherein the p-type electrode is formed as a single layer or a multi-layer.

11. The method of claim 2, wherein the p-type compound semiconductor layer is formed of a p-GaN layer.

12. The method of claim 2, wherein the p-type compound semiconductor layer is formed as a multi-layer, and the uppermost layer of the p-type compound semiconductor layer that contacts the p-type electrode is formed of a p-GaN layer.

13. A method for manufacturing a light emitting device, the method comprising:
forming at least one layer of n-type compound semiconductor layer on a substrate;
forming an active layer on the n-type compound semiconductor layer, the active layer where light is generated;
forming at least one layer of p-type compound semiconductor layer on the active layer;
annealing twice the resultant structure including the p-type compound semiconductor layer;
forming a p-type electrode on the p-type compound semiconductor layer; and
forming an n-type electrode to contact the n-type compound semiconductor layer.

14. The method of claim 13, wherein annealing twice the resultant structure comprises:
performing first annealing on the resultant structure in a nitrogen atmosphere; and
performing second annealing on the first annealed resultant structure in an oxygen atmosphere.

15. The method of claim 14, wherein the first annealing is performed at an atmospheric pressure at a temperature of 300-1000° C. for a duration from 30 seconds to 3 hours.

16. The method of claim 14, wherein the second annealing is performed at an atmospheric pressure at a temperature of 300-1000° C. for a duration from 30 seconds to 3 hours.

17. The method of claim 13, wherein the p-type electrode is formed as a single layer or a multi-layer.

18. The method of claim 17, wherein the single layer is formed of a Pd layer, a Ni layer, a Pt layer, or an Au layer.

19. The method of claim 17, wherein the multi-layer is formed of at least two layers selected from the group consisting of a Pd layer, a Ni layer, a Pt layer, and an Au layer.

20. The method of claim 13, wherein the p-type compound semiconductor layer is formed of a p-GaN layer.

21. The method of claim 13, wherein the p-type compound semiconductor layer is formed as a multi-layer, and the uppermost layer of the p-type compound semiconductor layer that contacts the p-type electrode is formed of a p-GaN layer.

22. The method of claim 14, wherein the p-type electrode is formed as a single layer or a multi-layer.

23. The method of claim 14, wherein the p-type compound semiconductor layer is formed of a p-GaN layer.

24. The method of claim 14, wherein the p-type compound semiconductor layer is formed as a multi-layer, and the uppermost layer of the p-type compound semiconductor layer that contacts the p-type electrode is formed of a p-GaN layer.
